(19) United States
(12) Patent Application Publication
(10) Pub. No.: US 2021/0243921 A1
(43) Pub. Date: Aug. 5, 2021

(54) WATER-COOLED POWER CONVERSION SYSTEM

(71) Applicant: Toshiba Mitsubishi-Electric Industrial Systems Corporation, Tokyo (JP)

(72) Inventor: Kenichiro OMOTE, Tokyo (JP)

(73) Assignee: Toshiba Mitsubishi-Electric Industrial Systems Corporation, Tokyo (JP)

(21) Appl. No.: 17/237,357

(22) Filed: Apr. 22, 2021

Related U.S. Application Data
(63) Continuation of application No. PCT/JP2018/039172, filed on Oct. 22, 2018.

(51) Int. Cl. H05K 7/20

(52) U.S. Cl. CPC H05K 7/20927

(57) ABSTRACT

A water-cooled power conversion system capable of reliably bleeding air in a short time is provided by simultaneously injecting cooling water and bleeding air into a main circuit unit. The water-cooled power conversion system consists of a main circuit board, a water supply apparatus, and a cooling apparatus, and the main circuit unit in the main circuit board comprises pressure-contacted semiconductor elements, water-cooled heat sinks arranged upper and lower surfaces of, and in close contact with the pressure-contacted semiconductor element, and an air bleeding valve located above the water flow pipe. The main circuit board includes a drain hose for flowing cooling water overflowing with air from the air bleeding valve, a drain pan for storing the cooling water discharged from the drain hose, a leak sensor for detecting the cooling water of the drain pan, and a control unit. The cooling apparatus includes a pump that pressurizes cooling water and injects water into the water-cooled heat sink, and the control unit operates the air leakage valve and the pump when the amount of water in the drain pan exceeds a predetermined value, control to finish injecting cooling water and bleeding air at the same time.

### CROSS-REFERENCE TO RELATED APPLICATION

This application is based upon and claims the benefit of priority from the prior PCT Patent Application No. PCT/JP2018/39172, filed on Oct. 22, 2018, the entire contents of which are incorporated herein by reference.

### TECHNICAL FIELD

The present invention relates to a water-cooled power conversion system.

### BACKGROUND ART

It is known that a large-capacity power conversion system adopts a water-cooled type for cooling elements such as semiconductors constituting a power converter. Such a water-cooled power conversion system is composed of a main circuit board containing the power converter, a water supply apparatus, a cooling apparatus, and the like.

The water supply apparatus stores the water supplied from the water supply port in a surge tank and supplies it to the cooling apparatus. The main circuit board uses main circuit units using semiconductor elements to form a power converter that is an inverter or a converter. The main circuit unit includes a semiconductor element as a switching element, a water-cooled heat sink and pipes arranged so as to cool the semiconductor element, a water outlet, a drain, and the like.

The cooling apparatus consists of a pump that sends and circulates cooling water, a heat exchanger, and the like. The cooling water sent from the pump of the cooling apparatus is introduced from the water passage port of the main circuit unit in the main circuit board via the heat exchanger and a mother pipe on a water entry side of the main circuit board. In the main circuit unit, the cooling water that has entered from the water passage port is discharged from the drain via the water-cooled heat sink. The heat released from the semiconductor element is dissipated to the cooling water via the water-cooled heat sink.

The warmed cooling water discharged from the drain returns to the pump of the cooling apparatus again via the mother pipe on a water inlet side of the main circuit board. The warmed cooling water is sent from the pump to the heat exchanger, cooled, and then sent again to the main circuit unit in the main circuit board via the mother pipe on the water inlet side of the main circuit board. In this way, the cooling water circulates in the water-cooled power conversion system.

In such a water-cooled cooling system, if air remains in the flow path through which the cooling water circulates, the cooling efficiency may decrease, so it is important to bleed the air in the flow path. Regarding the air bleeding method of the water-cooled cooling system, a technique relating to the cooling liquid replenishment method of the air conditioning system and the air conditioning system capable of efficiently bleeding air in the cooling circuit and the air conditioning circuit has been published (for example, Patent Document 1).

### PRIOR ART DOCUMENT

### Patent Document

Patent Document 1: Japanese Patent Publication No. 2016-107952

### SUMMARY OF THE INVENTION

### Problem to be Solved by the Invention

However, in the water cooling method described above, since the cooling flow path is complicated, there is a problem that it is difficult to remove air and it takes time and effort when trying to fill water in the case there exists a plurality of main circuit units. In addition, there is a problem that water needs to be replenished when the water level in the surge tank drops due to air bleeding. The present invention is made to solve the above-mentioned problems, and an object of the present invention is to provide a power conversion system having a structure capable of easily bleeding air.

### Means for Solving the Problem

In order to achieve the above object, a power conversion apparatus according to claim 1 of the present invention comprises the main circuit board comprising a plurality of main circuit units with same configuration; same number of drain hoses as the number of the main circuit units; same number of drains as the number of the main circuit units; same number of leakage sensors as the number of the main circuit units; a control unit; the main circuit unit involving: semiconductor elements; water-cooled heat sinks arranged so as to contact with cooling surface of the semiconductor elements; a water outlet through which cooling water cooled by the cooling apparatus is passed through the water-cooled heat sink; a drain for draining the cooling water taken into the main circuit unit from the water outlet; a pipe connecting the cooling apparatus to the water outlet or the drain, or between the water outlet and the water-cooled heat sink so that cooling water flow; an air bleeding valve located at the top of the pipe connecting the water outlet and the water-cooled heat sink, one end of the drain hose is connected to the air bleeding valve of the plurality of main circuit units, and the other end is configured so that water flowing through the drain hose from the air bleeding valve is flowed to the drain, the water leakage sensor outputs a water leakage detection signal when the flow rate of the cooling water flowed to the drain exceeds a predetermined value, the control unit is connected so as to be able to receive the leak detection signal from the leak sensor, the water supply apparatus is equipped with a surge tank and a water supply port, and the water supplied from the water supply port is stored in the surge tank, and the water is supplied to the cooling apparatus, the cooling apparatus is equipped with a pump that pressurizes the cooling water supplied from the surge tank and the water discharged from the drain port, and injects the water into the water-cooled heat sink through the pipe and the water outlet, and, the pump is connected so as to be able to control its start and stop operation from the control unit.

### Effects of the Invention

According to the present invention, cooling water injection operation and air bleeding can be continuously and easily performed.

### BRIEF DESCRIPTION OF THE DRAWINGS

FIG. 1 is a configuration diagram of a water-cooled power conversion system according to a first embodiment of the present invention.

FIG. 2 is a flowchart showing processing according to a first embodiment of the present invention.

FIG. 3 is a flowchart showing details of an operation confirmation process of the water leakage sensor according to the first embodiment of the present invention.

FIG. 4 is a flowchart showing processing of a first modification of the first embodiment of the present invention.

FIG. 5 is a flowchart showing processing of a second modification of the first embodiment of the present invention.

FIG. 6 is a flowchart showing details of an operation confirmation process of a water leakage sensor according to the second modification of the first embodiment of the present invention.

FIG. 7 is a block diagram of a water-cooled power conversion system according to a second embodiment of the present invention.

FIG. 8 is a flowchart showing processing according to the second embodiment of the present invention.

### EMBODIMENT TO PRACTICE THE INVENTION

Hereinafter, embodiments of the present invention will be described with reference to the drawings.

### First Embodiment

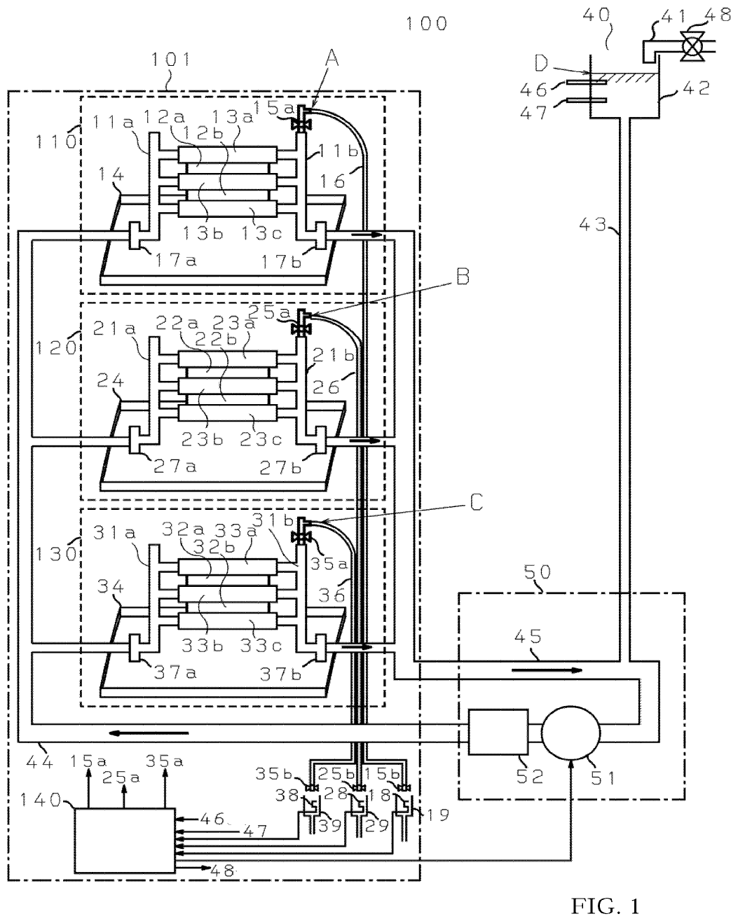

FIG. 1 is a configuration diagram of the water-cooled power conversion system 100 according to the first embodiment, and is an example of a case where the main circuit board 101, the water supply apparatus 40, and the cooling apparatus 50 are configured. The illustrated main circuit board 101 shows a case where the main circuit units 110, 120, and 130 using semiconductor elements are configured. Each main circuit unit is for a power converter such as an inverter or a converter. The illustrated main circuit board 101 shows a case where three main circuit units are stacked, but the number of main circuit units is not limited to this. It depending on the specifications of the power converter.

Here, since the main circuit units 110, 120, and 130 have the same configuration, the main circuit unit 110 will be described as a representative. Further, it is assumed that the main circuit units 110, 120, and 130 are stacked from the top in this order. The main circuit unit 110 includes pressure-contacted semiconductor elements 12a and 12b such as IGBTs, water-cooled heat sinks 13a, 13b and 13c arranged so as to be in close contact with the upper and lower surfaces of these pressure-contacted semiconductor elements, and it is composed of pipes 11a and 11b and a drain pan 14, an air bleeding valve 15a, a drain hose 16, a water outlet 17a, and a drain port 17b.

The water-cooled heat sinks 13a, 13b, 13c and the pressure-contacted semiconductor elements 12a, 12b arranged between the water-cooled heat sinks 13a, 13b, 13c are pressure-contacted from top and bottom to the inside by not illustrated pressure-contact means, which are arranged above the water-cooled heat sink 13a and below the water-cooled heat sink 13c.

As a result, the pressure contact surface, that is, the cooling surface of the pressure-contacted semiconductor elements 12a, 12b is pressure-contacted to the water-cooled heat sinks 13a, 13b, 13c, and the heat released from the pressure-contacted semiconductor element is dissipated to the water-cooled heat sink.

Normally, during the operation of the water-cooled power conversion system, the cooling water sent from the pump 51 of the cooling apparatus 50 is cooled by the heat exchanger 52. Then, it flows into the pipe 11a arranged inside the main circuit unit 110 from the water passage port 17a via the mother pipe 44. Further, the cooling water is injected into the water-cooled heat sinks 13a, 13b, 13c and discharged from the drain port 17b via the pipe 11b.

The water-cooled heat sinks 13a, 13b, 13c are cooled by cooling water to cool the pressure-contacted semiconductor element that is in pressure-contacting with the water-cooled heat sinks 13a, 13b, 13c. Further, the air bleeding valve 15a is closed during the operation of the water-cooled power conversion system 100.

The cooling water heated by cooling the pressure-contacted semiconductor elements 12a and 12b passes through the mother pipe 45 from the drain port 17b and returns to the cooling apparatus 50. The cooling water returned to the cooling apparatus 50 is sent from the pump 51 to the heat exchanger 52, cooled by the heat exchanger 52, and then sent to the mother pipe 44. In this way, the cooling water is circulated.

The drain pan 14 is a tray for preventing the cooling water from falling and scattering discharged when passing water through the main circuit unit 110 or bleeding air described above, or water droplets due to dew condensation generated on piping or the like. The air bleeding valve 15a is the valve for bleeding air accumulated in the pipe 11b, and is a valve that can be opened and closed by being attached to the uppermost part of the pipe 11b. A drain hose 16 is connected to the air bleeding valve 15a. The inner diameter of the air bleeding valve 15a and the inner diameter of the drain hose 16 are smaller than the inner diameter of the pipe 11b. That is, the pressure loss from the air bleeding valve 15a to the air bleeding valve 15b via the drain hose 16 is made sufficiently larger than the pressure loss in the path from the drain port 17b to the inlet of the pump 51 via the mother pipe 45.

Since the viscosity of air is sufficiently smaller than that of water, even if the pressure loss in the air bleeding path is large, it does not hinder air bleeding. Further, by increasing the pressure loss in the air bleeding path, the amount of drainage at the time of air bleeding can be reduced.

Here, the water-cooled heat sinks 13a, 13b, 13c, and the connection portion between the drain port 17b and the pipe 11b are arranged so as to be located below the uppermost portion of the pipe 11b. By arranging in this way, the air in the cooling water collects at the uppermost portion of the pipe 11b.

The air bleeding valve 15a is an electromagnetic drain valve that controls the flow of air or cooling water in the piping by opening and closing the valve with an electric signal to bleed air. A signal for controlling the opening and closing of the air bleeding valve 15a is transmitted from the control unit 140.

The main circuit unit 120 involves pressure-contacted semiconductor elements 22a, 22b, water-cooled heat sinks 23a, 23b, 23c, pipes 21a, 21b, drain pan 24, air bleeding valve 25a, drain hose 26, water outlet 27a, and drain 27b. Since the connections and operations between the components are the same as those of the main circuit unit 110, the description thereof will be omitted. The main circuit unit 130 has pressure-contacted semiconductor elements 32a, 32b, water-cooled heat sinks 33a, 33b, 33c, pipes 31a, 31b, drain pan 34, air bleeding valve 35a, drain hose 36, water outlet 37a, and drain 37b. Since the connections and operations between the components are the same as those of the main circuit unit 110, the description thereof will be omitted.

In addition to the above, air bleeding valves 15b, 25b, 35b, water leakage detectors 18, 28, 38, and drains 19, 29, 39 are provided in the main circuit board 101. The air bleeding valve 15b is connected to the other end of the drain hose 16 to which the air bleeding valve 15a is connected, and the drain 19 is provided below the air bleeding valve 15b to be discharged the cooling water together with air from the air bleeding valve 15b. Here, the air bleeding valve 15b is placed at a position sufficiently lower than the air bleeding valve 15a.

A sufficiently low position means that the potential energy due to the height difference between the air bleeding valves 15a and 15b is large with respect to the pressure loss of the leaked cooling water passing through the drain hose 16, and the pressure loss does not hinder the passage of the leaked cooling water. It means that the height difference can be secured.

The cooling water discharged to the drain 19 is discharged to the outside of the main circuit board 101 via a pipe not illustrated. A water leakage detector 18 is provided inside the drain 19, and when the flow rate or the discharge amount of the cooling water discharged to the drain 19 is equal to or higher than a predetermined value, the water leakage is detected and a water leakage detection signal is transmitted to the control unit 140.

Since the configurations of the drain hoses 26 and 36, the air bleeding valves 25b and 35b, the leak detectors 28 and 38, and the drains 29 and 39 are the same as above, the description thereof will be omitted.

The water supply apparatus 40 is a portion that supplies water from the outside, stores the water supplied from the water supply port 41 in the surge tank 42, and supplies the water to the cooling apparatus 50 via the pipe 43. It is preferable that the surge tank 42 is arranged at a position higher than the height of the path through which the cooling water flows, such as the pipes 11a, 11b of the main circuit board 101 or the water-cooled heat sinks 13a, 13b, 13c. That is, the cooling water surface D stored in the surge tank 42 is arranged so as to be higher than the position A of the air bleeding valve 15a. Further, the surge tank 42 is connected to the mother pipe 45 via the pipe 43.

With such an arrangement, air bleeding becomes easy by utilizing the potential energy of water in the surge tank 42. The pump 51 is on/off controlled by the control unit 140. Further, the surge tank 42 is provided with a first water level sensor 47 and a second water level sensor 46. Water is supplied to the surge tank 42 from a water source not illustrated by opening the water supply valve 48. The detected water level of the second water level sensor 46 is set higher than the detected water level of the first water level sensor 47. The output of the first water level sensor 47 and the output of the second water level sensor 46 are connected to the control unit 140. By using the water supply valve 48 as an electromagnetic valve, opening and closing can be automatically performed by the control unit 140.

The cooling apparatus 50 pressurizes the water supplied from the surge tank 42 and the water discharged from the drains port 17b, 27b, and 37b by the pump 51, cools it by the heat exchanger 52, and sends it to water outlet 17a,27a, and 37a through the mother pipe 44.

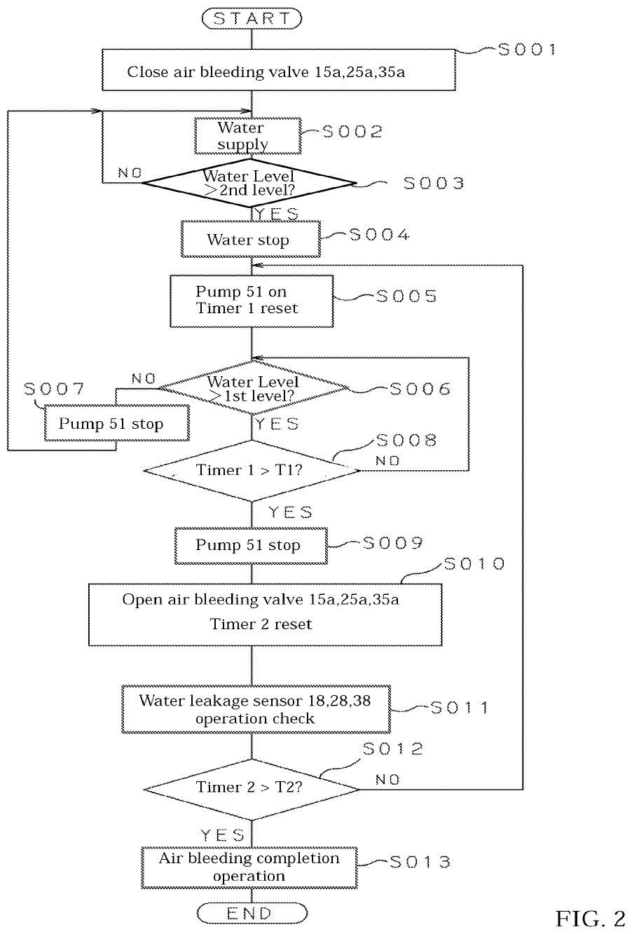

FIG. 2 is a flowchart in the case where cooling water is injected and air is bleeded before operating the water-cooled power conversion system 100 in the first embodiment.

Here, the processing such as flushing of the cooling pipe is omitted. Further, here, it is assumed that the air bleeding valves 15b, 25b, and 35b are opened in advance.

The air bleeding method is performed by repeating the following steps (1) to (3) multiple times after filling the flow path with cooling water.

(1) The pump 51 is operated for a set time of T1, and stopped.
(2) After the pump is stopped, the air accumulated in the upper part of the pipes 11b, 21b, 31b is evacuated from the flow path by opening the air bleeding valves 15a, 25a, 35a.
(3) The air bleeding valves 15a, 25a and 35a are closed.

The reason why the steps (1) to (3) are repeated multiple times is that the air in the pipe is generally dispersed in the pipe as bubbles, and it is difficult to evacuate all the air in the pipe by one air bleeding operation.

In step S001, the air bleeding valves 15a, 25a, and 35a are closed by the signal from the control unit 140.

Next, in step S002, the water supply valve 48 is opened by a signal from the control unit 140, and water from a water source not illustrated is supplied to the surge tank 42 through the water supply port 41. The water supplied to the surge tank 42 fills the cooling apparatus 50 as cooling water via the pipe 43, and further, the water-cooled part of the main circuit units 110, 120 and 130 in the main circuit board 101 is filled by the water via the mother pipes 45 and 44. When the cooling water is filled in this way, the water level in the surge tank 42 also rises.

Next, in step S003, the control unit 140 determines whether or not the water level of the surge tank 42 is equal to or higher than the predetermined second water level based on the signal from the second water level sensor 46.

If the water level in the surge tank 42 is less than the second water level (NO in S003), return to step S002 and continue water injection. When the water level of the surge tank is higher than the second water level (YES in S003), the process proceeds to step S004.

In step S004, the control unit 140 issues a command to the water supply valve 48 to close the valve, and stops the water supply.

Next, in step S005, the control unit 140 commands the pump 51 to operate for water supply. When the pump 51 operates, the cooling water is pressurized by the pump 51 as described above, flows from the heat exchanger 52 via the mother pipe 44, and flows through the mother pipe 45 via the flow path in the main circuit board 101, and circulates to the pump 51. When the cooling water circulates in this way, since the air remaining in the flow path is lighter than the cooling water, it collects at the uppermost part in the flow path. That is, air is collected on the upper part of the pipe 11b.

Further, the control unit 140 resets the timer 1 to 0 in order to operate the pump 51 for the set time T1. After that, the timer 1 starts measuring the passage of time.

Next, in step S006, the control unit 140 determines whether the water level of the surge tank is equal to or higher than the first water level based on the signal from the first water level sensor 47. When the cooling water is pressurized by the pump 51, the air in the cooling pipe is compressed and the water level may drop. In addition, in the subsequent steps, since a part of the cooling water is discharged to the outside of the water channel together with the air, the water level may drop. Therefore, judge step S006 is the necessary step. When it is determined that the water level of the surge tank is less than the first water level (NO in S006), the process proceeds to step S007, the pump 51 is temporarily stopped, and the process returns to the water injection step of step S002 to inject water. These steps can prevent air from entering the flow path from the surge tank 42.

When the control unit 140 determines in step S006 that the water level of the surge tank is equal to or higher than the first water level (YES in S006), the control unit 140 proceeds to step S008 and determines whether or not the elapsed time of the timer 1 exceeds the set time T1. If the elapsed time of the timer 1 does not exceed the set time T1 (NO in S008), the process returns to step S007, and the pump 1 continues to operate. If the elapsed time of the timer 1 exceeds the set time T1 (YES in S008), the process proceeds to step S009 and the pump 51 is stopped.

Next, in step S010, the control unit 140 opens the air bleeding valves 15a, 25a, and 35a and resets the timer 2 to 0. After that, the timer 2 starts measuring the passage of time.

Next, in step S011, the control unit 140 performs operation check process of the water leakage sensors 18, 28, and 38. The operation check process determines whether or not water leakage has been detected for each of the water leakage sensors 18, 28, and 38. If water leakage is detected, the corresponding air bleeding valves 15a, 25a, and 35a are closed. This is a procedure for carrying out the work until all the valves 15a, 25a and 35a are closed.

When the air bleeding valves 15a, 25a, 35a are opened in step S010, since the water level D of the surge tank 42 is higher than the position A of the air bleeding valve 15a, even if the pump is stopped, the air remaining on the upper part of the pipes 11b, 21b,31b is discharged from the air bleeding valves 15a, 25a, 35a via the drain hoses 16, 26, 36, and from the air bleeding valves 15b, 25b, 35b, respectively.

After the exhaust of the air remaining on the upper parts of the pipes 11b, 21b, 31b is completed, the cooling water of the pipes 11b, 21b, 31b is subsequently discharged from the air bleeding valves 15a, 25a, 35a to the drain hoses 16, 26, 36. Then the air is discharged from the air bleeding valves 15b, 25b, 35b to the drains 19, 29, 39, respectively. Cooling water is discharged to the drains 19, 29, and 39. Since the drains 19, 29, and 39 are provided with water leakage sensors 18, 28, and 38, when the flow rate or the discharge amount exceeds a predetermined value, water leakage is detected, and a signal is outputted.

Therefore, when the water leakage detection signal is detected from the water leakage sensors 18, 28, 38, it can be determined that the exhaust of the air remaining in the upper part of the corresponding pipes 11b, 21b, 31b has been completed. When a water leakage detection signal is detected, the control unit 140 closes the air bleeding valves 15a, 25a, 35a above the corresponding pipes 11b, 21b, 31b.

By closing the air bleeding valves 15a, 25a, 35a, unnecessary cooling water drainage can be reduced. When all the air bleeding valves 15a, 25a and 35a are closed, the process proceeds to step S012.

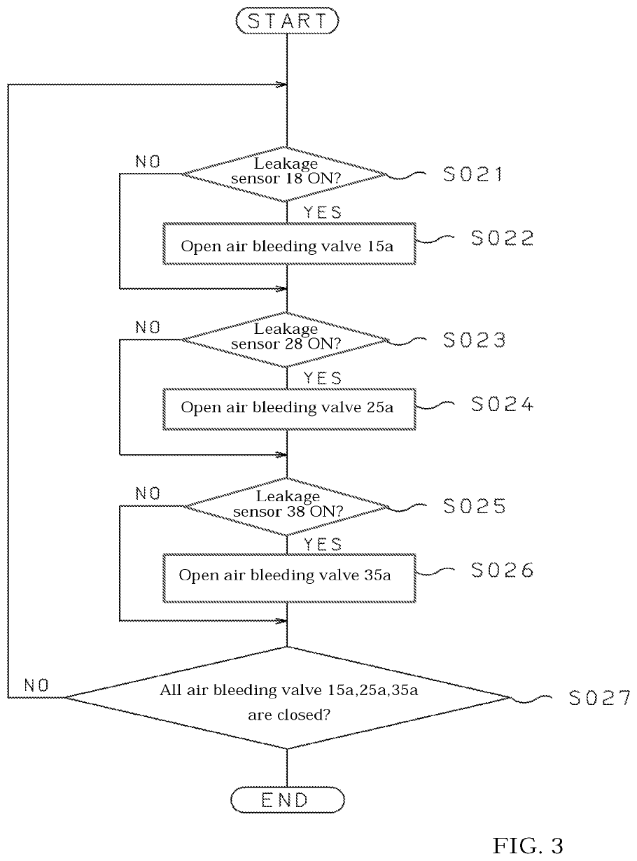

The details of the step S011 which is the water leakage sensor operation check process will be described with reference to FIG. 3.

First, the control unit 140 determines in step S021 whether or not there is a water leakage detection signal from the water leakage sensor 18, and if a water leakage detection signal is detected (YES in step S021), the air bleeding valve 15a is closed in step S022 and the process proceeds to step S023. If the leak detection signal is not detected (NO in step S21), the process proceeds to step S023 directly.

In step S023, the control unit 140 determines whether or not there is a water leakage detection signal from the water leakage sensor 28, and if a water leakage detection signal is detected (YES in step S023), the air bleeding valve 25a is closed in step S024, and move to step S025. If the water leakage detection signal is not detected (NO in step S023), the process proceeds to step S025 directly.

In step S025, the control unit 140 determines whether or not there is a water leakage detection signal from the water leakage sensor 38. If a water leakage detection signal is detected (YES in step S025), the air bleeding valve 25a is closed in step S026, and move to step S027. If the water leakage detection signal is not detected (NO in step S025), the process proceeds to step S027 directly.

In step S027, the control unit 140 determines whether all three of the air bleeding valves 15a, 25a, and 35a are closed. When all three of the air bleeding valves 15a, 25a, and 35a are closed (YES in step S027), it is determined that the water leakage sensor operation confirmation process is completed. If even one is not closed (NO in step S027), the process returns to step S021.

Return to FIG. 2 and explain. In step S012, it is determined that whether or not the air bleeding of the main circuit board 101 is completed. In the embodiment shown in FIG. 2, it is determined whether or not the air bleeding is completed by the time of the timer 2 not exceeding the set time T2.

When the time of the timer 2 exceeds the set time T2 (NO in step S012), the process returns to step S005, the pump 51 is operated again to circulate the cooling water, and the residual air in the flow path is gathered to the top of the pipes 11b, 21b, 31b by a series of operations. If the time of the timer 2 does not exceed the set time T2 (YES in step S012), the process proceeds to step S013. That is, if there is residual air in the upper part of the pipes 11b, 21b, 31b, water leakage is detected after the air bleeding valves 15a, 25a, 35a are opened, and then the remaining air is exiting via drain hose 16, 26, 36. Therefore, when there is no air remaining in the upper part of the pipes 11b, 21b, 31b, the time after the air bleeding valves 15a, 25a, 35a are opened until water leakage is detected and the air bleeding valves 15a, 25a, 35a are closed is shorter than when there is air remaining in the upper part of the pipes 11b, 21b, 31b. Therefore, when the air bleeding valves 15a, 25a, 35a are closed within the set time T2 (YES in step S012), the air bleeding in the flow path is completed and the process proceeds to step S013.

In step S013, an end signal is outputted to a display device or an external device not illustrated as an air bleeding completion procedure. Therefore, the air bleeding procedure can be easily completed by performing the above-mentioned process by the control unit 140.

In this embodiment, the air bleeding valves 15a, 25a, 35a may be omitted. Further, the water leakage sensors 18, 28, 38 may be arranged not in the drains 19, 29, 39 but in the drain pans 14, 24, 34, and the drain water of the drain hoses 16, 26, 36 may be arranged to lead in the drain pans 14, 24, 34, respectively.

As described above, according to the present invention, it is possible to provide a water-cooled power conversion system capable of continuously and easily injecting cooling water and bleeding air. In addition, since the pressure loss from the air bleeding valve to the drain via the drain hose is made sufficiently large than the pressure loss from the drain port to the path from the drain port to the inlet of the pump 51 via the mother pipe 45 on the water discharge side of the main circuit board, the amount of drainage when bleeding air is small, and the amount of make-up water can be reduced.

### First Modified Example of First Embodiment

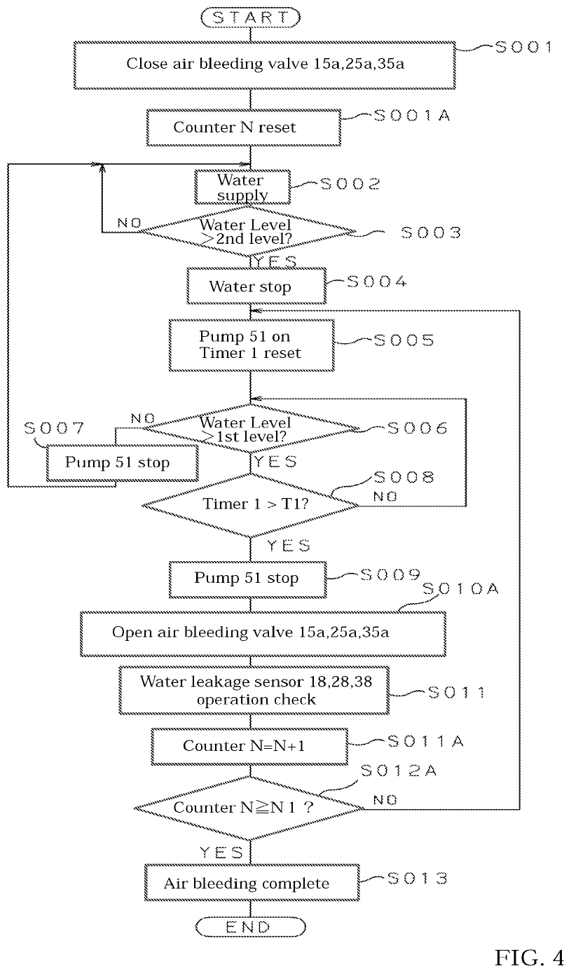

FIG. 4 is a flow chart of modified example according to the first embodiment of the present invention. In FIG. 2, the control unit 140 determines that the air bleeding treatment is completed based on whether the measurement time of the timer 2 is within the set time T2, but here, it is judged that the air bleeding procedure is completed when the operation check process of the water leakage sensors 18, 28, and 38 in step S011 is performed at the predetermined number of times (N).

The main differences from FIG. 2 in FIG. 4 are as follows.

(1) Step S001A is added between step S001 and step S002. Step S001A is a process of resetting the number counter N of the water leakage sensor 18, 28, 38 operation check process to 0.

(2) The procedure for resetting the timer 2 in step S010 is deleted. Instead of this, step S010A having only the procedure of opening the air bleeding valves 15a, 25a, 25a is inserted.

(3) Step S011A is added after step S011. Step S011A is a process of increasing the number of times counter N of the water leakage sensors 18, 28, 38 operation check processes by 1.

(4) Step S012A is inserted in place of step S012 after step S011A. In step S012A, it is determined whether the counter N is equal to or higher than the preset value N1. If the counter N has a value N1 or more (YES in step S012A), the air bleeding in the flow path is completed, and the process proceeds to step S013. If the counter N is less than the value N1 (NO in step S012), the process returns to step S005.

When the control unit 140 performs a predetermined number of times (N) the above-mentioned process, that is the operation check process of the water leakage sensors 18, 28, 38 by starting and stopping the pump 51 and opening and closing the air bleeding valves 15a, 25a, 35a, the air bleeding procedure can be easily completed.

As described above, according to the present invention, it is possible to provide a water-cooled power conversion system and a main circuit board capable of easily injecting cooling water and bleeding air.

### Second Modified Example of the First Embodiment

In the configuration of FIG. 1, the air bleeding valves 15a, 25a, 35a have been described as solenoid valves, but the air bleeding valves 15a, 25a, 35a and the air bleeding valves 15b, 25b, 35b may be manual valves. Further, the air bleeding valves 15b, 25b, 35b are arranged close to each other, and the air bleeding valves 15b, 25b, 35b are arranged at positions that are easy for the operator to operate. Further, the control unit 140 is provided with means for notifying the operator of the operating state (start, stop) of the pump 51 and the states of the water leakage sensors 18, 28, 38 (presence or absence of the water leakage detection signal). The means for notifying may be a liquid crystal display or other display device, or may be a means such as an alarm sound.

Further, the water-cooled power conversion system includes a circuit for transmitting a signal (air bleeding valve fully closed signal) indicating that the air bleeding valves 15b, 25b, 35b have all closed to the control unit 140. The circuit that transmits to the control unit 140 that all of the air bleeding valves 15b, 25b, and 35b are closed may be a switch operated by an operator, or may be a switch that mechanically interlocks with the air bleeding valves 15b, 25b, and 35b. The air bleeding valves 15b, 25b, and 35b are examples of auxiliary air bleeding valves.

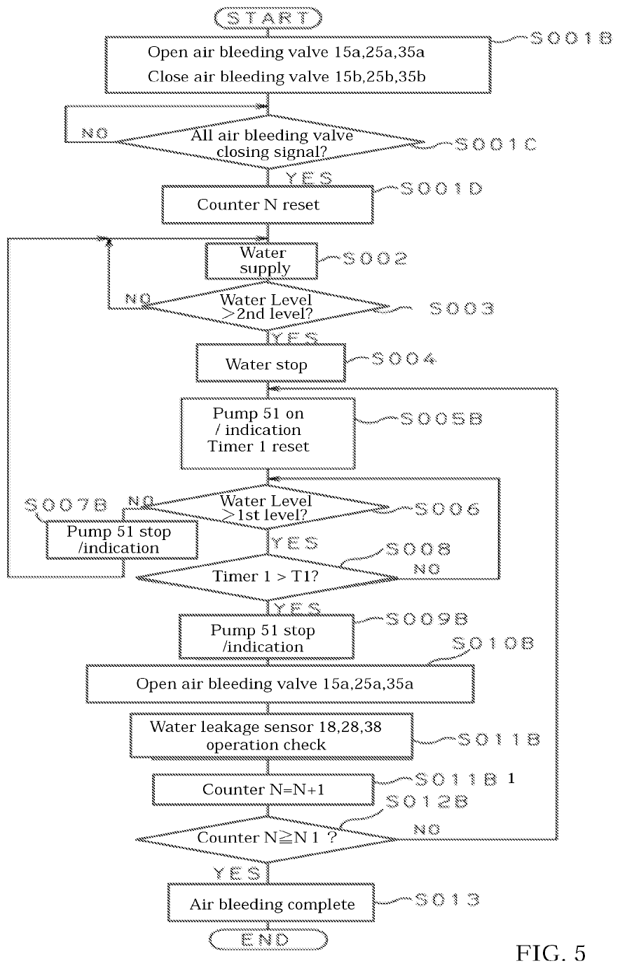

The operation flow of the second modification according to the first embodiment of the present invention will be described with reference to FIG. 5.

In step S00lB, the operator opens the air bleeding valves 15a, 25a, 35a and closes the air bleeding valves 15b, 25b, 35b. Further, an air bleeding valve fully closed signal is sent to the control unit 140 by an operator's operation or mechanical interlocking.

In step S001C, the control unit 140 determines whether or not the air bleeding valve fully closed signal has been received. If it is received (YES in step S001C), the process proceeds to step S001D. If it has not been received (NO in step S001C), it waits in step S001C.

The air bleeding valve fully closed signal is a signal indicating that all three of 15b, 25b, and 35b are closed. Here, the air bleeding valves 15a, 25a, 35a are open, and the air bleeding valves 15b, 25b, 35b are closed.

In step S001D, the control unit 140 resets the number of operation check process counters of the water leakage sensors 18, 28, and 38 to 0 in the same manner as in step S001A in FIG. 4, and then the process proceeds to step S002. Since the movements from step S002 to step S004 are the same as those in the first embodiment, the description thereof will be omitted.

Next, in step S005B, the control unit 140 commands the pump 51 to operate for water supply, and the control unit 140 resets the timer 1 to set the time to zero in order to operate the pump 51 for the set time T1, and after that, the timer 1 start measurement the time elapsed. Further, the operator is notified that the pump 51 is operating.

If the control unit 140 determines in step S006 that the water level of the surge tank 42 is less than the first water level (NO in S006), the process proceeds to step S007B, temporarily stops the pump 51, and notifies to the operator of the stopped state of the pump.

Further, the process returns to the water injection step of step S002 to inject water. When the control unit 140 determines in S006 that the water level of the surge tank is equal to or higher than the first water level (YES in S006), the process proceeds to step S008.

If the elapsed time of the timer 1 does not exceed the set time T1 in step 0008 (NO in S006), the process returns to step S006. When the elapsed time of the timer 1 exceeds the set time T1 (YES in S008), the control unit 140 proceeds to step S009B to stop the pump and notifies the operator stopped state of the pump 51.

Next, in step S010B, the operator opens the air bleeding valves 15b, 25b, and 35b after confirming the stopped state of the pump 51.

Next, in step S011B, the control unit 140 performs the operation check process of the water leakage sensors 18, 28, and 38. The operation check process determines whether or not water leakage has been detected for each of the water leakage sensors 18, 28, and 38, and if water leakage is detected, notifies the operator the water leakage detection of the corresponding sensor.

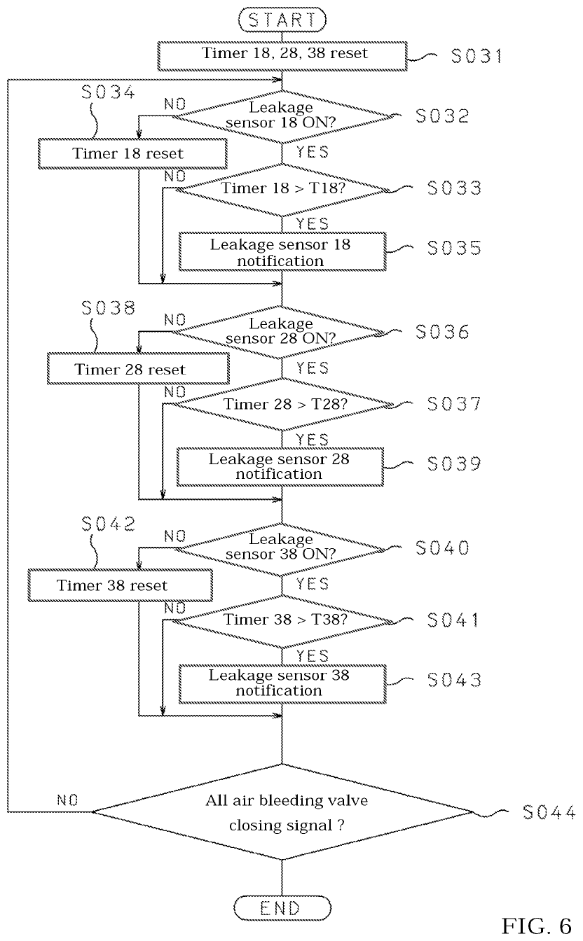

If the air bleeding valve fully closed signal is received, the process proceeds to the next step. The details of step S011B will be described with reference to FIG. 6.

FIG. 6 shows the detailed steps of step S011B. The control unit 140 resets the timers 18, 28, and 38 for measuring the water leakage duration for each water leakage sensor to 0 in step S031, and proceeds to step S032.

The control unit 140 determines in step S032 whether or not there is a water leakage detection signal from the water leakage sensor 18. When the leak detection signal is detected (YES in step S032), if the time measurement of the timer 18 has not been started, the measurement is started, and if the time measurement has been performed, the measurement is continued and the process proceeds to step S033.

If the water leakage detection signal is not detected in step S032 (NO in step S032), the process proceeds to step S034, the timer 18 is reset, and the process proceeds to step S036.

The control unit 140 determines in step S033 whether or not the timer 18 exceeds the predetermined set time T18, and if it exceeds (YES in step S033), the process proceeds to step S035. If it does not exceed (NO in step S033), the process proceeds to step S036.

The control unit 140 notifies the operator the operation of the leak sensor 18 in step S035, and proceeds to step S036.

The control unit 140 determines in step S036 whether or not there is a water leakage detection signal from the water leakage sensor 28. When the leak detection signal is detected, YES in step S036) if the time measurement of the timer 28 is not started, the measurement is started, if the time has been measured, the measurement is continued, and the process proceeds to step S037. If the water leakage detection signal is not detected in step S036 (NO in step S036), the process proceeds to step S038, the timer 28 is reset, and the process proceeds to step S040.

The control unit 140 determines in step S037 whether or not the timer 28 exceeds the predetermined set time T28, and if it exceeds (YES in step S037), the process proceeds to step S039. If it does not exceed (NO in step S037), the process proceeds to step S040.

In step S039, the control unit 140 notifies the operator the operation of the leak sensor 28, and proceeds to step S040.

The control unit 140 determines in step S040 whether or not there is a leak detection signal from the leak sensor 38, and when the leak detection signal is detected (YES in step S040), if the time measurement of the timer 38 is not started, the measurement is started, and if the time has been measured, the process is continued, and the process proceeds to step S041. If the water leakage detection signal is not detected in step S040 (NO in step S040), the process proceeds to step S042, the timer 38 is reset, and the process proceeds to step S044.

The control unit 140 determines in step S041 whether or not the timer 38 exceeds the predetermined set time T38, and if it exceeds (YES in step S042), the process proceeds to step S043. If it does not exceed (NO in step S042), the process proceeds to step S044.

The control unit 140 notifies the operator the operation of the leak sensor 38 in step S043, and proceeds to step S044.

In the next step S044, the control unit 140 determines whether or not the air bleeding valve fully closed signal has been received. When the air bleeding valve fully closed signal is not received (NO in step S044), the process returns to step S032, and when the signal is received (YES in step S044), it is determined that the water leakage sensor operation check process (step S011B) is completed.

The operator performs the following operations while the control unit 140 is performing the repeated steps from steps S032 to S044. That is, the air bleeding valves 15b, 25b, and 35b are closed, which corresponds to the water leakage detector operated by the notification of the water leakage detection of the control unit 140.

When the operator closes all of the air bleeding valves 15b, 25b, 35b, the operator sends an air bleeding valve fully closed signal to the control unit 140, or a valve fully closed signal is transmitted to the control unit 140 by a circuit that is linked to the air bleeding valves 15b, 25b, 35b.

As a result, the control device 140 notifies the condition of YES in step S044, and can determine that the water leakage sensor operation check process (step S011B) is completed. The set times T18, T28, and T38 are time limits for preventing unnecessary operation of the water leakage detectors 18, 28, and 38 due to the cooling water remaining in the drain hoses 16, 16, and 36.

Returning to FIG. 5, a description will be given. Since the steps from step S011 to step S013 are the same as the first modification of the first embodiment, the description thereof will be omitted.

As described above, the air bleeding operation can be easily completed when the control unit 140 performs start and stop of the pump 51 and notification the operator thereof, and the operation check process of the water leakage sensors 18, 28, and 38, in a predetermined number of times (N). The operator can easily complete the air bleeding procedure by opening and closing the air bleeding valves 15b, 25b, 35b according to the notification of the control unit 140.

As described above, according to the present invention, it is possible to provide a water-cooled power conversion system and a main circuit board capable of easily injecting cooling water and bleeding air.

### Second Embodiment

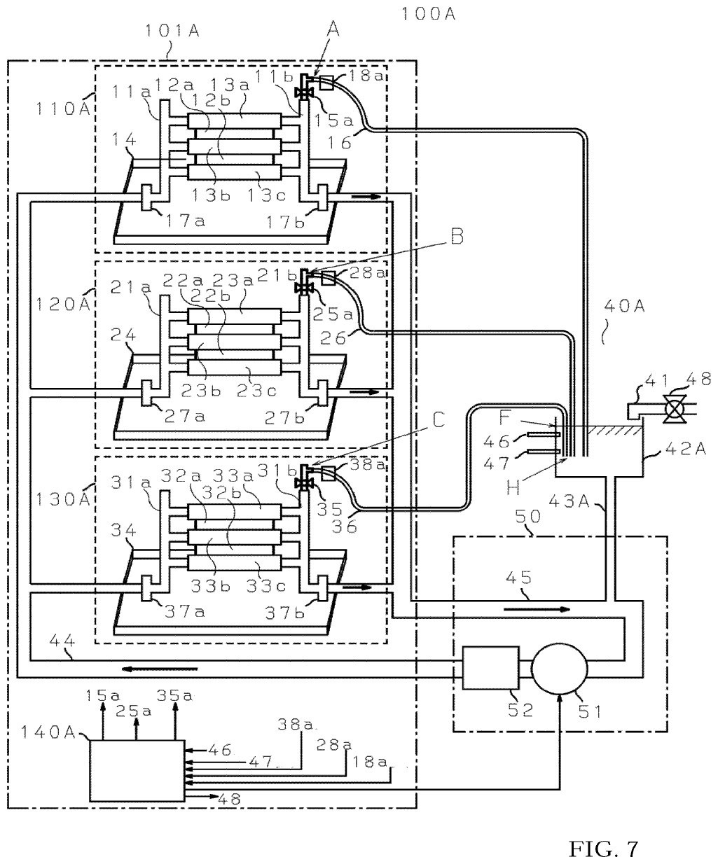

FIG. 7 is a configuration diagram of the water-cooled power conversion system 100A according to the second embodiment of the present invention, and is an example in the case where the main circuit board 101A, the water supply apparatus 40A, the cooling apparatus 50, and the like are configured. Regarding each part of the second embodiment, the same parts as each part of the configuration diagram of the water-cooled power conversion system 100A according to the embodiment of the present invention in FIG. 1 are indicated by the same reference numerals, and the description thereof will be omitted.

The difference between the second embodiment and the first embodiment is that the air bleeding valves 15b, 25b, 35b at the ends of the drain hoses 16, 26, 36 are omitted, and the bubble sensors 18a, 28a, 38a are provided instead of the leak sensors 18, 28, 38 located in the main circuit board 101. The bubble sensors 18a, 28a, 38a are provided in the main circuit unit 110A, 120A, 130A, so as to detect bubbles in the drain hoses 16, 26, 36, respectively, and their outputs are connected to the control unit 140.

Further, the ends of the drain hoses 16, 26, 36 on the opposite side to the ends connected to the air bleeding valves 15a, 25a, 35a are laid up to the inside of the surge tank 42A, and it is arranged that the height H of the tip is arranged below the detection position of the first water level sensor 47.

In the water supply apparatus 40 of the first embodiment, the position of the cooling water surface D of the surge tank 42 is arranged at a position higher than the position A of the air bleeding valve 15a, but there is no such restriction in the second embodiment. That is, the position of the cooling water surface F of the surge tank 42A in the water supply apparatus 40A may be lower than the position A of the air bleeding valve 15a.

When the drain hoses 16, 26, 36 are made of a transparent material, the bubble sensors 18a, 28a, 38a can use an optical sensor or an ultrasonic sensor. When the drain hoses 16, 26 and 36 are made of an opaque material, ultrasonic sensors can be used as the bubble sensors 18a, 28a and 38a.

In FIG. 7, the bubble sensors 18a, 28a, 38a are provided inside the main circuit units 110A, 120A, 130A, but they may be located outside the main circuit units 110A, 120A 130A, where the bubbles of the drain hoses 16, 26, 36 can be detected.

When the position of the cooling water surface F of the surge tank 42A is lower than the position A of the air bleeding valve 15a, it is difficult to bleed the air remaining on the upper part of the pipe 11b except when the pump 51 is operating, due to the pressure relationship thereof. Therefore, in the second embodiment, since the air bleeding valves 15a, 25a, 35a are opened while the pump 51 is operating, the air remaining on the upper portions of the pipes 11h, 21b, 31b is discharged from the flow path of the water-cooled power conversion system 100A via the drain hoses 16, 26, 36. The air discharged from the drain hoses 16, 26, and 36 is discharged into the cooling water of the surge tank 42A, and further discharged into the atmosphere from the cooling water surface of the surge tank 42A.

Not only air but also cooling water is discharged from the drain hoses 16, 26, 36, but since it is discharged into the cooling water of the surge tank 42A, the cooling water is finally never discharged to the outside of the water-cooled power conversion system 100A.

The control unit 140 monitors the outputs of the bubble sensors 18a, 28a, 38a while the pump 51 is operating. Then, the control unit 140 determines that the air bleeding is completed when the bubble sensors 18a, 28a, 38a do not continuously detect bubbles for a predetermined period while the pump 51 is operating.

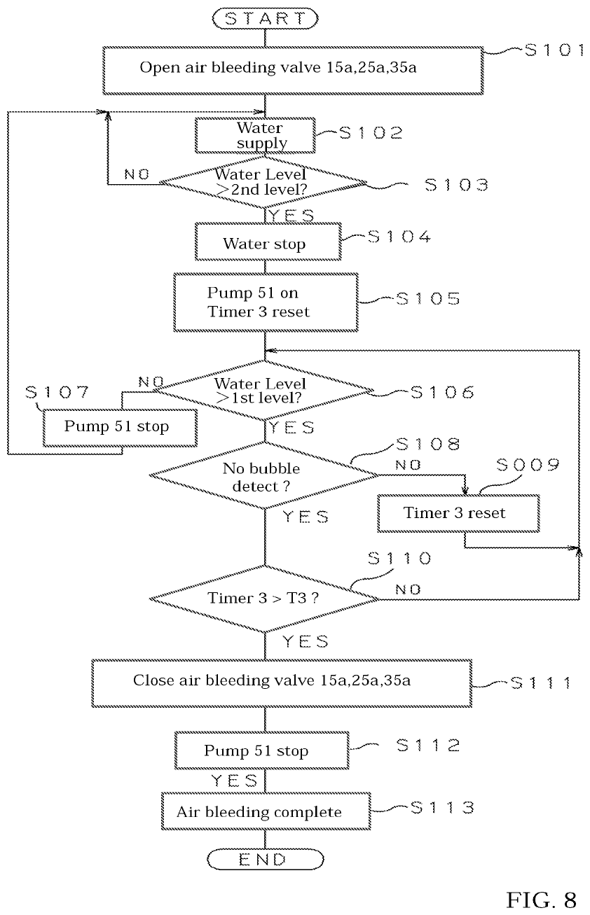

FIG. 8 is a flowchart in the case where cooling water is injected and air is bleeded before operating the water-cooled power conversion system 100A in the second embodiment. Here, the processing such as flushing of the cooling pipe is omitted.

In step S101, the air bleeding valves 15a, 25a, and 36a are opened by the signal from the control unit 140A.

The movement from step S102 to step S104 is basically the same as the movement from step S002 to step S004 in the first embodiment.

In step S102, the water supply valve 48 is opened by a signal from the control unit 140, and water from a water source (not shown) is supplied to the surge tank 42A through the water supply port 41.

In step S103, the control unit 140A determines whether or not the water level of the surge tank 42A is equal to or higher than the predetermined second water level based on the signal of the second water level sensor 46. If the water level of the surge tank 42A is less than the second water level (NO in step S103), the process returns to step S102. When the water level of the surge tank is higher than the second water level (YES in step S103), the process proceeds to step S104.

In step S104, the control unit 140A issues a closing command to the water supply valve 48.

Next, in step S105, the control unit 140A commands the pump 51 to be operated. When the pump 51 operates, the cooling water circulates in the flow path in the water-cooled power conversion system 100A. When the cooling water circulates in this way, the air remaining in the flow path collects in the upper part of the pipes 11b, 21b, 31b. Further, the control unit 140A resets the timer 3 for time measurement to 0. After that, the timer 3 starts measuring the passage of time.

The movements of step S106 and step S107 are basically the same as the movements of step S106 and step S107 in the first embodiment.

In step S106, the control unit 140A determines whether the water level of the surge tank is equal to or higher than the first water level based on the signal from the first water level sensor 47. If it is determined that the water level of the surge tank is less than the first water level (NO in step S106), the process proceeds to step S107, the pump 51 is temporarily stopped, and the process returns to the water injection step of step S102. When the control unit 140A determines in step S106 that the water level of the surge tank is equal to or higher than the first water level (YES in step S106), the process proceeds to step S108.

In step S108, the control unit 140A detects the outputs of the bubble sensors 18a, 28a, 38a, and when bubbles are detected from one or more bubble sensors (NO in step S108), the process proceeds to step S109. If no bubbles are detected from all the bubble sensors 18a, 28a, 38a (YES in step S108), the process proceeds to step S110.

In step S109, the control unit 140A resets the timer 3 for time measurement to zero, and returns to step 106.

In step S110, when the timer 3 for time measurement exceeds the preset time T3 (YES in step S110), the control unit 140A shifts to step 111. If the timer 3 for time measurement does not exceed the preset time T3 (NO in step S110), the process returns to step S106.

By repeating the procedure from step S106 to step S110 for a predetermined time of T3 or more, the control unit 140A can be determined that sufficient air has been released from the flow path of the water-cooled power conversion system 100A, so that the control unit 140A is informed that no bubbles are detected from all the bubble sensors 18a, 28a, 38a.

In step S111, the control unit 140A outputs a command to close the air bleeding valves 15a, 25a, and 36a. As a result, it is possible to prevent air entering from the drain hoses 16, 26, 36 on the surge tank 42A side to the flow path of the water-cooled power conversion system 100A, when the pump 51 is stopped and an unexpected drop in water level occurs in the surge tank 42A for some reason and the water level drops below the position H in FIG. 7.

In step S112, the control unit 140A outputs a signal for stopping the pump 51 and stops the pump 51. Then, the process proceeds to step S113.

In step S113, an end signal is outputted to a display device or an external device (not shown) as an air bleeding completion procedure. Therefore, when the control unit 140 performs the above-mentioned processing, the water injection and air bleeding treatment can be easily completed.

When the air bleeding valves 15a, 25a, and 35a are manually operated valves, a circuit for transmitting the opening and closing of the air bleeding valve to the control apparatus is provided, and the timer in the control unit 140A is provided that notify the timer 3 has passed the set time T3 or more.

Further, after the control unit 140A receives the following information, the process may be performed that the operator manually close the air bleeding valves 15a, 25a, 35a and transmit this information to the control unit 140A, then move to step S112. The following information is that the operator manually opens the air bleeding valves 15a, 25a, 35a in step S101, transmits this information to the control unit 140A, and move to step S102, then the control unit 140A informs to the operator that that the time of the timer 3 has passed the set time T3 or more in step 111.

The set time T3 depends on the scale of the water-cooled power conversion system, etc., but is preferably about several tens of minutes to several hours, for example.

Although the example using the bubble sensor has been described in the second embodiment, the water leakage sensor may be used as in the first embodiment.

As described above, according to this second embodiment, it is possible to provide a water-cooled power conversion system capable of easily injecting cooling water and bleeding air.

In addition, since the cooling water discharged together with the air at the air bleeding is returned to the surge tank from the air bleeding valve via the drain hose, the drainage at the air bleeding is basically eliminated, and the amount of make-up water can be reduced.

As described above, according to the present invention, it is possible to provide a water-cooled power conversion system capable of easily injecting cooling water and bleeding air.

### EXPLANATION OF SYMBOLS

100, 100A water-cooled power conversion system
101, 101A main circuit board
110, 120, 130 main circuit unit
110A, 120A, 130A main circuit unit
11a, 11b, 21a, 21b, 31a, 31b, piping
12a, 12b, 22a, 22b, 32a, 32b, pressure-contacted semiconductor elements
13a, 13b, 13c, 23a, 23b, 23c, 33a, 33b, 33c, water-cooled heat sink
14, 24, 34 drain pan
15a, 25a, 35a air bleeding valve
15b, 25b, 35b air bleeding valve
16, 26, 36 drain hose
17a, 27a, 37a water outlet
17b, 27b, 37b drain port
18, 28, 38 leakage sensor
18a, 28a, 38a bubble sensor
19, 29, 39 drain
40, 40A water supply apparatus
41 water supply port
42, 42A surge tank
43, 43A piping
44, 45 mother pipe
46 second water level sensor
47 first water level sensor
48 water supply valve
50 cooling apparatus
51 pump

1. A water-cooled power conversion system equipped with a main circuit board, a water supply apparatus, and a cooling apparatus,
wherein,
the main circuit board comprises:
a plurality of main circuit units with same configuration;
same number of drain houses as the number of the main circuit units;
same number of drains as the number of the main circuit units;
same number of leakage sensors as the number of the main circuit units;
a control unit;
the main circuit unit involves:
semiconductor elements;
water-cooled heat sinks arranged so as to contact with cooling surface of the semiconductor elements;
a water outlet through which cooling water cooled by the cooling apparatus is passed through the water-cooled heat sink;
a drain port for draining the cooling water taken into the main circuit unit from the water outlet;
a pipe connecting the cooling apparatus to the water outlet or the drain, or between the water outlet and the water-cooled heat sink so that cooling water flow;
an air bleeding valve located at the top of the pipe connecting the water outlet and the water-cooled heat sink;
one end of the drain hose is connected to the air bleeding valve of the plurality of main circuit units, and the other end is configured so that water flowing through the drain hose from the air bleeding valve is flowed to the drain,
the water leakage sensor outputs a water leakage detection signal when the flow rate of the cooling water flowed to the drain exceeds a predetermined value,
the control unit is connected so as to be able to receive the leak detection signal from the leak sensor,
the water supply apparatus is equipped with a surge tank and a water supply port, and the water supplied from the water supply port is stored in the surge tank, and the water is supplied to the cooling apparatus,
the cooling apparatus is equipped with a pump that pressurizes the cooling water supplied from the surge tank and the water discharged from the drain port, and injects the water into the water-cooled heat sink through the pipe and the water outlet, and,
the pump is connected so as to be able to control its start and stop operation from the control unit.

2. The water-cooled power conversion system according to claim 1, wherein
the surge tank is provided with a first water level sensor that detects the first water level, and when the first water level sensor detects that the water level is less than the first water level, the pump is stopped and water is injected into the surge tank from the water supply port so that the water level of the surge tank is kept above a predetermined water level, and
the air bleeding valve is installed at a position lower than the first water level of the surge tank, wherein after the pump is operated for a first predetermined period of time, the pump is stopped, the air bleeding valve is opened, and an air bleeding procedure is performed.

3. The water-cooled power conversion system according to claim 2, wherein
the air bleeding valve is composed of valves that can be operated by opening/closing commands from the control unit,
The control unit outputs a closing command to the air bleeding valve corresponding to the water leakage detection signal, when the control unit receives the water leakage detection signal from the water leakage sensor, and
the air bleeding procedure is completed when the control unit receives the water leakage detection signals from all the water leakage sensors within a period not exceeding the second predetermined time from the opening command of the air bleeding valve.

4. The water-cooled power conversion system according to claim 2, wherein
the air bleeding valve is composed of valves that can be operated by opening/closing commands from the control unit,
the control unit involves;
as a first procedure, the pump is operated for a first predetermined period;
as a second procedure, stop the pump;
as the third procedure, the air bleeding valve open command is outputted and when the control unit receives the water leakage detection signal from the water leakage sensor, a closing command is outputted to the air bleeding valve corresponding to the water leakage detection signal;
as a fourth procedure, when a closing command is outputted to all the air bleeding valves, the process proceeds to a fifth procedure.
as the fifth procedure, when the number of repetitions from the first procedure to the fourth procedure is less than a predetermined number, the process returns to the first procedure, and when the number of repetitions is more than a predetermined number, the air bleeding procedure is completed.

5. The water-cooled power conversion system according to claim 2, wherein
the drain hose is equipped with an auxiliary air bleeding valve on the drain side, and
the control unit further comprising circuit for notifying the operator of the operating state of the pump and the water leakage detection signal, and circuit for electrically receiving signal that the auxiliary air bleeding valve closed by and the operator or the interlocking signal with the auxiliary air bleeding valve.

6. The water-cooled power conversion system according to claim 1, wherein
the surge tank is equipped with a first water level sensor for detecting the first water level and a second water level sensor for detecting a second water level higher than the first water level, and
the operation of the pump is started after the water injection in the surge tank is completed up to the water level of the second water level sensor when starting water injection of the water-cooled power conversion system.

7. A water-cooled power conversion system equipped with a main circuit board, a water supply apparatus, and a cooling apparatus,
wherein,
the main circuit board comprises:
a plurality of main circuit units with same configuration;
same number of drain hoses as the number of the main circuit units;
same number of bubble sensors as the number of the main circuit units;
a control unit;
the main circuit unit involves:
semiconductor elements;
water-cooled heat sinks arranged so as to contact with cooling surface of the semiconductor elements;
a water outlet through which cooling water cooled by the cooling apparatus is passed through the water-cooled heat sink;
a drain for draining the cooling water taken into the main circuit unit from the water outlet;
a pipe connecting the cooling apparatus to the water outlet or the drain, or between the water outlet and the water-cooled heat sink so that cooling water flow;
an air bleeding valve located at the top of the pipe connecting the water outlet and the water-cooled heat sink;
one end of the drain hose is connected to the air bleeding valve of the plurality of main circuit units,
the bubble sensor is attached to the drain hose so that bubbles can be detected in the drain hose, and outputs a bubble detection signal when bubbles are detected,
the water flowing through the drain hose or the surge tank is flowed from the air bleeding valve,
the control unit is connected so as to be able to receive the bubble detection signal from the bubble sensor,
the water supply apparatus is equipped with a surge tank and a water supply port, and the water supplied from the water supply port is stored in the surge tank, and the water is supplied to the cooling apparatus,
the cooling apparatus is equipped with a pump that pressurizes the cooling water supplied from the surge tank and the water discharged from the drain port, and injects the water into the water-cooled heat sink through the pipe and the water outlet, and,
the pump is connected so as to be able to control its start and stop operation from the control unit.

8. The water-cooled power conversion system according to claim 7, wherein
a first water level sensor is provided to detect the first water level,
when the first water level sensor detects that the water level is less than the first water level, the pump is stopped and water is injected into the surge tank from the water supply port, and
the end of the drain hose on the surge tank side is arranged below the first water level.

9. The water-cooled power conversion system according to claim 7, wherein
the control unit terminates the air bleeding treatment when the bubble detection signal is not continuously received for a third predetermined period during the operation of the pump.
